(19) United States
(12) Patent Application Publication
(10) Pub. No.: US 2011/0215820 A1
(43) Pub. Date: Sep. 8, 2011

(54) Delta detection method for detecting capacitance changes

(75) Inventors: Richard Lalau, North Vancouver (CA); Damir Wallener, North Vancouver (CA); Lockland Corley, Coquitlam (CA); Andrew Jackman, Langley (CA); Alex Trampolski, Richmond (CA); Matthew Friesen, Surrey (CA)

(73) Assignee: DISPENSING DYNAMICS INTERNATIONAL

(21) Appl. No.: 12/660,790

(22) Filed: Mar. 4, 2010

(51) Int. Cl. G01R 27/26

(52) U.S. Cl. 324/686

(57) ABSTRACT

A delta detection method for detecting capacitance changes caused by relative movement between a physical object and a capacitance sensor.

This application includes a computer program listing Appendix in the form of a compact disc (two identical copies). The files of the compact disc are specified in an Attachment located at the end of the specification and before the claims hereof.

### TECHNICAL FIELD

This invention relates to a delta detection method for detecting capacitance changes caused by relative movement between a physical object and a capacitance sensor.

### BACKGROUND OF THE INVENTION

It is well known to employ capacitive sensing to initiate or control the operation of various types of apparatus and systems. For example, it is known to utilize capacitance sensors to initiate operation of paper towel dispensers and other dispensers by sensing proximity of a user's hand.

Described below in greater detail are traditional approaches commonly practiced for both analog and digital detection when utilizing capacitance sensors to detect the location of physical objects. The prior art approaches have a number of drawbacks which also will be described below. One of these drawbacks is “ghosting”, or the incorrect interpretation of a noisy signal as a valid detection event.

### DISCLOSURE OF INVENTION

The unique method of the present invention as encompassed in software detects capacitance changes while also filtering out false triggers. The invention employs delta detection methodology as the basis for calculating changes in capacitance.

The delta detection method of the invention is for detecting capacitance changes caused by relative movement between a physical object and a capacitance sensor.

The method includes the step of obtaining a sequence of signal readings from the capacitance sensor during the relative movement.

The method also incorporates the step of establishing a plurality of time period based counting windows, each counting window encompassing a selected portion of the sequence of signal readings differing from the selected portions of the sequence of signal readings encompassed by the other of the counting windows.

The sequence of signal readings is stored as collected raw data.

The collected raw data is utilized to calculate the delta values between selected counting windows.

The calculated delta values are stored in an array of delta values.

The step of searching for a predetermined event based on the array of delta values is also a part of the method.

Other features, advantages and objects of the present invention will become apparent with reference to the following description and accompanying drawings.

### BRIEF DESCRIPTION OF DRAWINGS

FIG. 1 is a capacitance/time diagram illustrating the principles of operation a conventional prior art detection approach;

FIG. 2 is a view similar to FIG. 1, illustrating the principles of operation of a second prior art detection method;

FIGS. 3 and 4 are diagrammatic illustrations relating to the method of the present invention;

FIG. 5 is a representation of an exemplary pattern searched by the algorithm of the method;

FIG. 6 illustrates the pattern of FIG. 5 in a linear representation;

FIG. 7 is a diagrammatic illustration showing the principles of operation of a multi-sample delta method in accordance with the teachings of the present invention;

FIG. 8 is a block diagram showing sequential steps carried out when practicing the method of this invention;

FIG. 9 is a perspective view illustrating a rotating paper towel support roll of a paper towel dispenser in operative association with a capacitance sensor when the method of the invention is employed to monitor and control rotation of a drum;

FIG. 10 illustrates the traditional prior art approach to dealing with capacitance sensed signals by smoothing or averaging them;

FIG. 11 illustrates the delta method of the present invention as applied to applications involving a rotating drum; and

FIGS. 12 and 13 are diagrammatic presentations of other approaches relating to the utilization of the delta detection method of this invention in conjunction with a rotating roller or drum.

### MODES FOR CARRYING OUT THE INVENTION

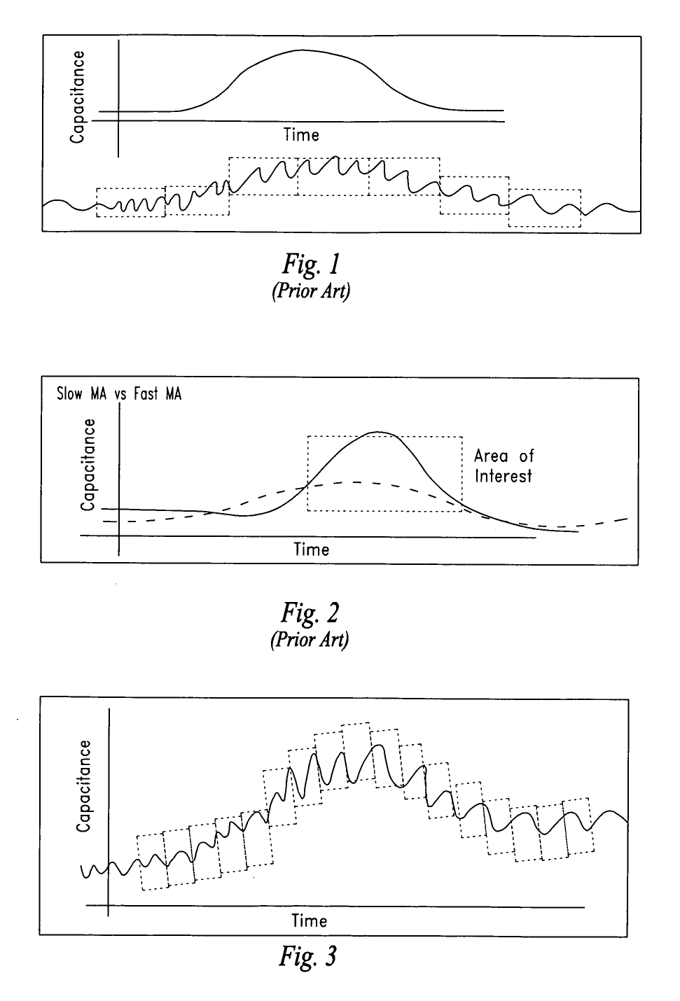

With reference to FIG. 1, in order to better understand how the method of the present invention differs from conventional detection methods, a brief explanation of a traditional approach that is commonly practiced for both analog and digital detection follows.

Each box depicted by dash lines in FIG. 1 represents a counting window, during which peaks from the sensor are counted and used as a proxy for the sensor's oscillation frequency. The length of the window is determined by the microcontroller's running frequency and a programmable internal timer.

The capacitance sensor forms what is essentially an antenna, and the oscillations from the sensor will not produce a single, stable frequency, but rather a noisy series of readings. One method for reducing the effect of the noise is to smooth out the signal (e.g. low-pass filter or average). This may be done with RC-type circuits in the analog domain or through signal processing in the digital domain. The smoothed out signal is depicted in FIG. 1 in a capacitance/time graph.

Multiple averages or different time-lengths may also be used. This is typically done by looking at times when an average of shorter time length crosses over or under an average of longer time length. This is shown in FIG. 2.

These methods have drawbacks for detecting short-duration events such as a hand wave. The FIG. 2 approach requires storage of two additional streams of numbers (one for each average). It is difficult to determine the “best” time lengths for averaging, as this changes with ambient noise levels. Long latency between when an event happens and when it is detected can be introduced.

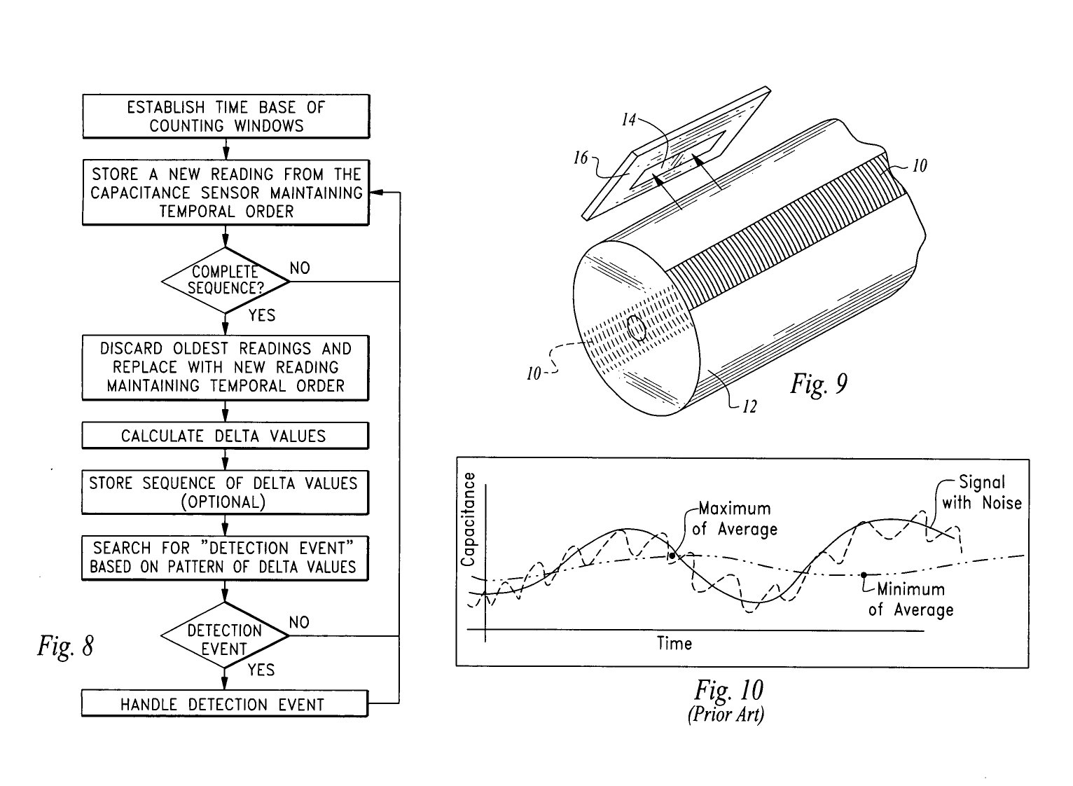

The method of the present invention is presented in block diagram form in FIG. 8 and is practiced utilizing coded software. Two CD copies of such software are attached as an Appendix.

Utilizing the delta detection method of the present invention, the starting point for processing data is the counting window. FIG. 3 shows relatively short counting windows applied to a single processing stream.

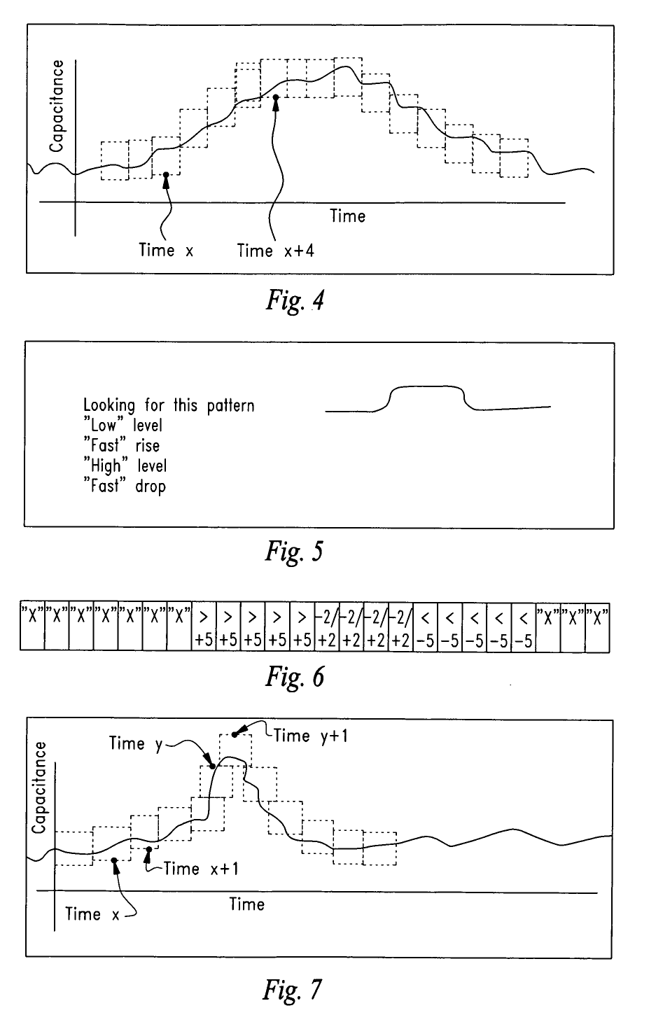

The sequence of readings is stored, usually in memory attached to a microcontroller or other programmable device. No averages are computed. Instead, the method looks at the difference between readings taken at different points in time. These points in time may in fact be consecutive readings, or they may be separated by a set or arbitrary length of time, as depicted in FIG. 4.

Using this collected raw data, the processing then proceeds as follows. The difference or the delta between counting windows is calculated and this is stored in an array of “delta” values. The length of the array is a function of the type of event detected, and the noise signal.

At the next appropriate time interval or time step, a new signal value is obtained. If the stored sequence of signal values is at its maximum length, the oldest value in the sequence may be dropped, and the new signal reading takes its place in a location that reflects the time-order of signal readings.

If the raw frequency were to be plotted, this array of delta values could be considered a proxy for the second derivative of the raw frequency curve. A detection event now becomes a specific pattern in this second derivative.

One example of what the algorithm will search for, while maintaining a lengthy array of delta values of suitable length, or an array of readings upon which each delta computations are performed at each time interval, is a pattern similar to a square wave pulse, such as depicted in FIG. 5. The pattern has a relatively flat “low” level, a sharp or “fast” rise from that “low” level, a short period of relative flatness at a “high” or elevated level, and a sharp drop from the elevated region. This paragraph refers to one possible exemplary pattern. Other detection events may have radically different signal signatures.

In a linear representation, this pattern match will look similar to that shown in FIG. 6 wherein an “X” denotes a “don't care” value, and the other entries specify a range of acceptable values for that location in the array of delta values. A detection event then becomes a ratio of matching vs. non-matching values across the array of deltas values.

The comparison values may be stored as an explicit sequence of values, or stored implicitly as a part of the mathematical function that performs event detection.

In some applications, one delta calculation may be insufficient to establish a detection event. The delta method can be extended to use multiple samples, across arbitrary lengths of time, as illustrated in FIG. 7.

FIG. 7 exemplifies an implementation where the delta method has a look-back time of four samples and requires a specific relationship between two sets of delta calculations.

In this case, the reading at time (Y+1) is compared to the reading at time (X+1), and the reading at time (X) is compared to the reading at time (Y). The two comparisons may look for the same threshold, or they may be independent tests.

For example, for a very sharp change in the signal, the comparison between X and Y may look for a small change and a large change between (X+1) or (Y+1). Alternately, a small change in a noisy environment may look for a moderate, identical change in both comparisons.

Multiple windows can also be used when storage space is limited, as more windows may allow storage of smaller amounts of data.

For paper towel dispensers and other types of dispensers that use a rotating roller mechanism to dispense product, it is necessary to control the rotation of the roller or drum in order to control the amount of dispensed product. One traditional method for doing this is the use of magnets and a sensor (Hall effect sensors or reed switches). By placing a magnet in a specific location on the drum, and a magnet sensor nearby, it is possible to count the revolutions of the drum roller. The drawbacks of this method include relatively high manufacturing expense, since magnets and sensors are expensive. Also, multiple magnets are required when one revolution of the roller does not provide sufficient control of the dispensed material.

Another traditional method is to use timers to control the length of time the motor driving the roller is energized. The primary drawback of this method is that it requires significant and ongoing calibration due to variability of power source to the motor and variability in the mechanical structure (“friction” is variable).

To overcome these limitations, capacitance sensing technology can be used to track drum/roller movement. This requires a relatively inexpensive sensor mounted near the roller and the placement of a strongly dielectric target material somewhere on the roller. In FIG. 9, a strip of metallic material (solid metal or adhesive foil) 10 is attached to the drum surface of drum or roller 12 in a way that the sensor can read the target material and, as the target passes by the sensor 14, a capacitance change corresponding to a detection event is recorded. The sensor may for example be a copper pad 14 within a printed circuit board 16.

Using capacitance sensing for tracking a rotating or otherwise periodically moving object poses challenges. The traditional prior art approach to dealing with capacitance sensed signals is to smooth or average them (FIG. 10). The solid line is the base with the noise superimposed and the noise line being depicted by dashes. The line depicted by dots and dashes is the smoothed average.

For a rotating device of circular shape, the signal generated should resemble something like a sine wave or other essentially periodic waveform of relatively stable frequency which is a function of the rotation speed of the roller. Thus, to detect a specific point on the rotating cylinder (drum or roller) passing near the sensor, it is only necessary to search for a peak value.

However, with noise it is possible the peak value with negative noise won't meet the threshold necessary to trigger a detection event. Or, a value with positive noise far from a peak event is sufficient to trigger a false detection.

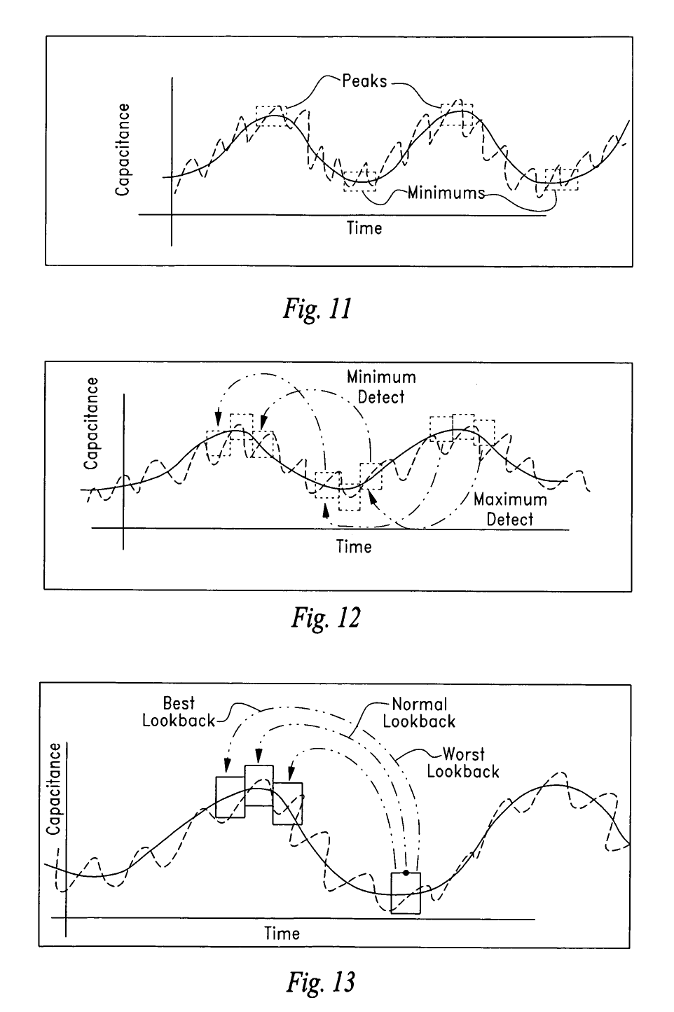

The proposed delta method for this particular application is the general delta method described above. The look-back distance between samples is a function of the sampling rate and the rotational speed of the cylinder (drum or roller). The counting window is small, to allow for multiple counts across the general maximum and minimum parts of the expected curve. See FIG. 11.

For random noise, this significantly increases the probability of detecting a peak while reducing the chance of a false positive. This is because a threshold value closer to the theoretical maximum distance between peaks and minimums can be used.

Two further variations or embodiments are proposed to deal with particularly challenging sensing environments as shown in FIG. 12.

The first variation uses multiple simultaneous deltas. This can be achieved in several ways, the simplest being to perform multiple comparisons at each point in time. With multiple comparisons, a detection event can be treated as a more complex “voting” scheme—e.g., two out of three delta compares meet a threshold.

The second variation is to detect both maximum and minimum values in the signal generated by the rotating object. This is shown in FIG. 12. This embodiment of the delta method alternates between searching for peaks and valleys. The operations can be considered inverse to each other: a peak may look for values above a high threshold; a valley may look for values below a low or negative threshold.

This is advantageous as it doubles the resolution at which the roller can be controlled, which allows for finer control of the quantity being dispensed by the roller or drum. The cost implications are obvious.

There may be implementations wherein the rotating object—e.g. a drum or roller spun by an electric motor, cannot maintain a constant rotational speed or cadence.

An example of how this can occur is in the case of a battery-powered motor, the batteries having been significantly depleted, cause a slowing rotation of the drum or roller. In the case of a paper dispenser where the paper is stored on a large roll, the rotational speed may be different between a full roll (heavy) and a nearly depleted roll (light). A further example is the possible effect of friction of the mechanical structure changing as the dispenser is used over time.

The delta method of this invention allows an approach for dealing with these variations in rotational speed. As shown in FIG. 13, the look-back distance for the delta calculation can be variable.

The variation of this look-back method distance is a function of the particular embodiment; for example, the look-back distance can be a function of the measured voltage at the battery terminals. Or the mechanical changes over time can be characterized, and the look-back distance can be calculated using an algorithm that understands the “aging” of the frictional resistance of the mechanical system.

The method steps of this invention can be carried out simultaneously with respect to multiple detection events. The method may include the step of selectively searching for different detection events.

The invention claimed is:

1. A delta detection method for detecting capacitance changes caused by relative movement between a physical object and a capacitance sensor, said method including the steps of:
obtaining a sequence of signal readings from the capacitance sensor during said relative movement;
establishing a plurality of time period based counting windows, each said counting window encompassing a selected portion of the sequence of signal readings differing from the selected portions of said sequence of signal readings encompassed by the other of said counting windows;
storing the sequence of signal readings as collected raw data;
utilizing the collected raw data, calculating the delta values between selected counting windows to provide an array of delta values;
searching for a predetermined detection event based on said array of delta values;
obtaining updated signal readings at periodic or otherwise programmed intervals;
updating the stored sequence of signal readings to incorporate the updated signal readings;
performing new calculations of delta values based on the updated stored sequence of signal readings to update the array of delta values; and
searching for the predetermined detection event based on the array of delta values after updating thereof.

2. The method according to claim 1 wherein said sequence of signal readings lies in a single processing stream.

3. The method according to claim 1 wherein said step of storing the sequence of signal readings comprises storing the sequence of signal readings in memory attached to a microcontroller or other programmable device.

4. The method according to claim 1 wherein the length of the array of delta values is a function of the type of predetermined detection event and noise signal from said capacitance sensor.

5. The method according to claim 1 wherein the search for said predetermined detection event based on the array of delta values is carried out by an established algorithm.

6. The method according to claim 5 wherein the algorithm searches for a specific pattern based on said array of delta values.

7. The method according to claim 6 wherein said pattern approximates that of a square wave pulse.

8. The method according to claim 5 wherein said predetermined detection event is represented by a ratio between matching and non-matching assigned values across the array of delta values.

9. The method according to claim 1 wherein the search for a predetermined event based on said array of delta values is carried out in points of time encompassed by consecutive counting windows.

10. The method according to claim 1 wherein the search for a predetermined event based on said array of delta values is carried out in points of time separated either by a set or arbitrary length of time.

11. The method according to claim 1 wherein the selected counting windows include sets of counting windows, the sets being spaced from one another, and wherein the delta values of the counting windows of each set are calculated.

12. The method according to claim 11 wherein the calculated detection values of the sets of counting windows are compared.

13. The method according to claim 1 wherein the selected counting windows are located at portions of the sequence of signal readings corresponding to the peaks and valleys of the sequence of signal readings.

14. The method according to claim 11 wherein the calculated delta values of counting windows of each set are calculated substantially simultaneously.

15. The method according to claim 1 wherein the steps are carried out simultaneously with respect to multiple detection events.

16. The method according to claim 1 including the additional step of selectively searching for different detection events.

17. The method according to claim 1 including the step of storing the calculated delta values.
